(19) United States
(12) Patent Application Publication
(10) Pub. No.: US 2017/0005214 A1
(43) Pub. Date: Jan. 5, 2017

(54) SOLAR CELL SEALING FILM, AND SOLAR CELL MODULE USING THE SAME

(71) Applicant: BRIDGESTONE CORPORATION, Tokyo (JP)

(72) Inventors: Akira YOSHITAKE, Yokohama-shi (JP); Hisataka KATAOKA, Yokohama-shi (JP)

(73) Assignee: BRIDGESTONE CORPORATION, Tokyo (JP)

(21) Appl. No.: 15/113,266

(22) PCT Filed: Jan. 23, 2015
(86) PCT No.: PCT/JP2015/051848

§ 371 Date: Jul. 21, 2016

(30) Foreign Application Priority Data
Jan. 23, 2014 (JP) 2014-010094

(51) Int. Cl. H01L 31/048; C08K 3/22

(52) U.S. Cl. CPC H01L 31/0481; C08K 3/22; C08K 2003/222; C08K 2003/2224

(57) ABSTRACT

There are provided: a solar cell-sealing film containing an ethylene-α-olefin copolymer polymerized using a metallocene catalyst, an organic peroxide and a silane coupling agent, wherein a decrease in the adhesive force of the sealing film during the storage time before its usage is suppressed; and a solar cell using the same. There are provided: a solar cell-sealing film formed of a composition containing an ethylene-α-olefin copolymer polymerized using a metallocene catalyst, an organic peroxide and a silane coupling agent, wherein the composition further contains 0.01 to 0.1 parts by mass of magnesium hydroxide or magnesium oxide with respect to 100 parts by mass of the ethylene-α-olefin copolymer, and the magnesium hydroxide or the magnesium oxide has a BET specific surface area of 30 m²/g or larger; and a solar cell using the same.

### TECHNICAL FIELD

The present invention relates to a solar cell sealing film comprising an ethylene-α-olefin copolymer polymerized using a metallocene catalyst, particularly to the solar cell-sealing film that does not tend to cause a decrease in the adhesive holding power during the storage time and is excellent in transparency.

### BACKGROUND ART

Conventionally, in view of the effective utilization of resources, the prevention of environmental pollution and the like, solar cell modules converting solar light directly into electric energy have been broadly used, and further, there has been progressed developments thereof for the power generation efficiency and the weather resistance, the reduction of the production cost, and the like.

A solar cell module is usually produced, as shown in FIG. 1, by stacking a front side transparent protection member 11 composed of a glass substrate or the like, a front side sealing film 13A, solar cells 14, such as silicon crystal power generation elements, a backside sealing film 13B and a backside protection member (back cover) 12 in this order, degassing the stack under reduced pressure, and thereafter heating and pressurizing the stack to crosslink to cure the front side sealing film 13 A and the backside sealing film 13B to thereby adhesively unify the stack. Then, in order to provide a high electric output, a plurality of the cell cells 14 are usually connected via interconnectors 15 composed of a conductive member, such as a copper foil, to use the solar cell; and the sealing films 13A and 13B which have high insulation properties are used in order to secure the insulation of the solar cells 14.

The developments of thin-film solar cell modules, including thin-film silicon-based, thin-film amorphous silicon-based solar cells and copper indium selenide (CIS)-based solar cells, have also been progressed; in this case, the solar cell is produced, for example, by forming a power generation element layer such as a semiconductor layer on the surface of a transparent substrate such as a glass or polyimide substrate by a chemical vapor deposition or the like, laminating a sealing film and the like thereon, and adhesively unifying the laminate.

In recent years, there has been developed a solar cell sealing material formed of a composition containing an ethylene-α-olefin copolymer polymerized using a metallocene catalyst (hereinafter, referred to also simply as “ethylene-α-olefin copolymer”) (for example, Patent Literature 1). Patent Literature 1 teaches that a sealing material formed of a composition containing an ethylene-α-olefin copolymer which has specific physical properties, and containing a light stabilizer and an ultraviolet absorbent is excellent in heat resistance, transparency, flexibility and durability, is suppressed in yellowing and can maintain a light conversion efficiency stabilized for a long period. It further discloses the followings: when an organic peroxide is incorporated in the sealing material, the sealing material can be crosslinked in a comparatively short time to exhibit a sufficient adhesive force to thereby achieve a reduction in the production cost of the solar cell module, which results in excellent productivity and a reduction in the production; and further by incorporating a silane coupling agent in the sealing material, the adhesive force to a glass substrate is improved.

### PRIOR ART LITERATURE

### Patent Literature

Patent Literature 1: JP 2012-44153 A

### SUMMARY OF INVENTION

### Problem to be Solved by the Invention

According to studies by the present inventors, however, it has been found that as for a solar cell sealing film containing an ethylene-α-olefin copolymer and further containing an organic peroxide and a silane coupling agent, in the case where the sealing film is used for production of a solar cell immediately after the production of the sealing film, a sufficient adhesive force is exhibited, but in the case where the sealing film is stored for a long period before its usage, the adhesive force decreases. Such a decrease in the adhesive force is sometimes caused when an ethylene-vinyl acetate copolymer (EVA), which is commonly used for solar cell sealing films, is used. However, the adhesive force is more likely to decrease in the case where an ethylene-α-olefin copolymer is used than in the case of using EVA. The cause of this is not clear, but it is conceivably due to bleedout (exudation of additives) of an organic peroxide and a silane coupling agent, and hydrolysis and easy gelation of a silane coupling agent having bled out.

Therefore, an object of the present invention is to provide a solar cell sealing film comprising an ethylene-α-olefin copolymer polymerized using a metallocene catalyst, an organic peroxide and a silane coupling agent, and being suppressed in a decrease in the adhesive force during the storage time before its usage; and a solar cell module using the same.

### Means for Solving the Problem

The above object is achieved by a solar cell sealing film formed of a composition comprising an ethylene-α-olefin copolymer polymerized using a metallocene catalyst, an organic peroxide and a silane coupling agent, wherein the composition further comprises 0.01 to 0.1 parts by mass of magnesium hydroxide or magnesium oxide with respect to 100 parts by mass of the ethylene-α-olefin copolymer, and the magnesium hydroxide or the magnesium oxide has a BET specific surface area of 30 m²/g or larger. By blending magnesium hydroxide or magnesium oxide, there can be prevented the decrease in the adhesive force in the storage time of the sealing film before its usage. Further by setting the amount of magnesium hydroxide or magnesium oxide blended to the above range, there can be secured the transparency essential for the solar cell sealing film and sufficiently exhibited the effect of improving the stability during the storage time.

The preferable embodiments of the solar cell sealing film according to the present invention are as follows.

(1) The magnesium hydroxide or magnesium oxide has a BET specific surface area of 30 to 200 m²/g.

(2) The magnesium hydroxide or magnesium oxide has a BET specific surface area of 50 to 160 m²/g.

(3) The magnesium hydroxide or magnesium oxide has an average particle diameter of 0.1 to 10 μm. When the average particle diameter of the magnesium hydroxide or magnesium oxide particles is too large, the transparency of the sealing film decreases in some cases; and when too small, the dispersibility of the magnesium hydroxide or magnesium oxide particles decreases in some cases.

(4) The melt flow rate (MFR) of the ethylene-α-olefin copolymer is 1 to 10 g/10 minutes as measured according to JIS K7210 under the condition of 190° C. and a load of 21.18 N. A composition excellent in moldability can be provided by fulfilling this condition.

(5) The haze value of the solar cell sealing film after crosslinked is 5.0 or lower as measured according to JIS K7105; and the light transmittance at a wavelength of 400 to 1,100 nm is 90.5% or higher. By fulfilling this condition, a sealing film having particularly high transparency can be provided, and such a sealing film can provide a solar cell exhibiting high light conversion efficiency.

Further the object is achieved by a method for producing a solar cell sealing film, comprising calender-molding a composition containing an ethylene-α-olefin copolymer polymerized using a metallocene catalyst, an organic peroxide and a silane coupling agent, and further containing 0.01 to 0.1 parts by mass of magnesium hydroxide or magnesium oxide having a BET specific surface area of 30 m²/g or larger with respect to 100 parts by mass of the ethylene-α-olefin copolymer. Particularly in this case, it is preferable that the melt flow rate (MFR) of the ethylene-α-olefin copolymer be 1 to 10 g/10 minutes as measured according to JIS K7210 under the condition of 190° C. and a load of 21.18 N. Thereby, a sealing film higher in the stability during the storage time can be provided.

Further the object is achieved by a solar cell obtained by sealing a solar cell element with the solar cell sealing film according to the present invention.

Further the object is achieved by a method for suppressing a decrease in the adhesive force during the storage time of a solar cell sealing film formed of a composition containing an ethylene-α-olefin copolymer polymerized using a metallocene catalyst, an organic peroxide and a silane coupling agent, wherein the composition further contains 0.01 to 0.1 parts by mass of magnesium hydroxide or magnesium oxide having a BET specific surface area of 30 m²/g or larger with respect to 100 parts by mass of the ethylene-α-olefin copolymer. Thereby, the decrease in the adhesive force can be suppressed without impairing the transparency of the solar cell sealing film even if the sealing film is stored for a long period before used for production of a solar cell module.

### Effects of Invention

In the present invention, since, a predetermined amount of magnesium hydroxide or magnesium oxide having a BET specific surface area of 30 m²/g or larger is further incorporated in the solar cell sealing film containing an ethylene-α-olefin copolymer polymerized using a metallocene catalyst, an organic peroxide and a silane coupling agent, the decrease in the adhesive force during the storage time is suppressed without impairing the transparency. Therefore, the solar cell module according to the present invention is a solar cell module high in the versatility in the production planning, reduced in the generation of faulty products, advantageous in the cost and high in the quality.

### BRIEF DESCRIPTION OF DRAWING

FIG. 1 is a schematic cross-sectional view of a usual solar cell.

### MODE FOR CARRYING OUT THE INVENTION

The solar cell-sealing film according to the present invention is formed of a composition containing an ethylene-α-olefin copolymer polymerized using a metallocene catalyst, an organic peroxide and a silane coupling agent, wherein the composition further contains 0.01 to 0.1 parts by mass of magnesium hydroxide or magnesium oxide having a BET specific surface area of 30 m²/g or more with respect to 100 parts by mass of the ethylene-α-olefin copolymer. As shown in Examples described later, by blending magnesium hydroxide or magnesium oxide, there can be prevented the decrease in the adhesive force during the storage time before the usage of the sealing film. This is conceivably because by incorporating magnesium hydroxide or magnesium oxide particles in the sealing film, there is prevented bleedout of the organic peroxide and the silane coupling agent during the storage time before the usage of the sealing film, and there is suppressed hydrolysis and gelation of the silane coupling agent having bled out. Further by setting the amount of magnesium hydroxide or magnesium oxide blended to the above range, there can be secured the transparency essential for the solar cell sealing film and sufficiently exhibited the effect of improving the stability during the storage time. The content of magnesium hydroxide or magnesium oxide in the composition is, with respect to 100 parts by mass of the ethylene-α-olefin copolymer, preferably 0.02 to 0.1 parts by mass, more preferably 0.03 to 0.09 parts by mass, and especially preferably 0.05 to 0.09 parts by mass.

In the present invention, magnesium hydroxide (Mg(OH)₂) or magnesium oxide (MgO) is not especially limited, and commercially available particulate ones can properly be used. When the average particle diameter of magnesium hydroxide or magnesium oxide is too large, the effect is likely to become local in some cases and when too small, the dispersibility in the composition decreases in some cases, which sometimes results in that the effect of preventing bleedout of the organic peroxide and the silane coupling agent, and the like are not sufficiently exhibited. Therefore, an average particle diameter of magnesium hydroxide or magnesium oxide particles is preferably 0.1 to 10 μm, more preferably 0.1 to 9 μm, still more preferably 0.1 to 8 μm, and especially preferably 3 to 8 μm.

The average particle diameter of magnesium hydroxide or magnesium oxide particles refers to a median diameter determined by a laser diffraction/scattering particle size distribution analysis.

A BET specific surface area of magnesium hydroxide or magnesium oxide particles is 30 m²/g or more, preferably 30 to 200 m²/g, and more preferably 50 to 160 m²/g. When the BET specific surface area is smaller than 30 m²/g, the adhesive force with glass cannot be maintained for a long period in some cases; and when the BET specific surface area is too large, the light transmission decreases in some cases, accompanied by the decrease in the dispersibility in the composition.

Hereinafter, materials for the composition according to the present invention will be described in detail.

[Ethylene-α-Olefin Copolymer Polymerized Using a Metallocene Catalyst]

The ethylene-α-olefin copolymer contained in the composition according to the present invention is an ethylene-α-olefin copolymer (including a terpolymer and the like) having as a main component a structural unit derived from ethylene, and further having one or more structural units derived from α-olefins having 3 to 12 carbon atoms such as propylene, 1-butene, 1-hexene, 1-octene, 4-methylpentene-1, 4-methyl-hexene-1, 4,4-dimethyl-pentene-1 and the like, and includes a so-called metallocene catalyst-linear low-density polyethylene (m-LLDPE). Specific examples of the ethylene-α-olefin copolymer include ethylene-1-butene copolymer, ethylene-1-octene copolymer, ethylene-4-methyl-pentene-1 copolymer, ethylene-butene-hexene terpolymer, ethylene-propylene-octene terpolymer and ethylene-butene-octene terpolymer. The content of an α-olefin in the ethylene-α-olefin copolymer is preferably 5 to 40% by mass, more preferably 10 to 35% by mass, and still more preferably 15 to 30% by mass. When the content of an α-olefin is low, the flexibility and impact resistance of the solar cell sealing film are not sufficient in some cases; and when too high, the heat resistance is low in some cases.

As the metallocene catalyst for polymerizing the ethylene-α-olefin copolymer, a known metallocene catalyst may be used, and the metallocene catalyst is not especially limited. The metallocene catalyst is usually a combination of a metallocene compound with an aluminum compound as a promoter such as an alkylaluminoxane, an alkylaluminum, an aluminum halide or an alkylaluminum halide, and the metallocene compound here is a compound having a structure in which a transition metal such as titanium, zirconium or hafnium is sandwiched between unsaturated cyclic compounds containing a cyclopentadienyl group, a substituted cyclopentadienyl group or the like, which is a π electron system. The metallocene catalyst is characterized by having homogeneous active sites (single site catalyst), and usually provide a polymer having a narrow molecular weight distribution and nearly the same contents of comonomers in the each molecule.

In the present invention, the density (according to JIS K7112, hereinafter, the same applies) of the ethylene-α-olefin copolymer is not especially limited, but is preferably 0.860 to 0.930 g/cm³, and more preferably 0.860 to 0.900 g/cm³. Further the melt flow rate (MFR) (according to JIS K7210) of the ethylene-α-olefin copolymer is not especially limited, but is, from the viewpoint of the moldability of the sealing film, preferably 1 g/10 minutes or higher, and particularly in the case where the sealing film is produced by calender molding as described later, it is more preferably 1 to 10 g/10 minutes, and still more preferably 2 to 5 g/10 minutes. Here, the MFR is measured under the condition of 190° C. and a load of 21.18 N.

In the present invention, as the ethylene-α-olefin copolymer, a commercially available one may be used. Examples thereof include Harmorex series and Kernel series, manufactured by Japan Polyethylene Corp., Evolue series, manufactured by Prime Polymer Co., Ltd., and Excellen GMH series and Excellen FX series, manufactured by Sumitomo Chemical Co., Ltd.

[Organic Peroxide]

The organic peroxide contained in the composition of the solar cell-sealing film according to the present invention can crosslink the ethylene-α-olefin copolymer by heating to react. Thereby, the solar cell-sealing film and other members can sufficiently be adhered, and the sealing film also becomes high in transparency. As the organic peroxide, any one can be used as long as it decomposes at a temperature of 100° C. or higher to generate radicals. The organic peroxide is usually selected in consideration of the film formation temperature, the preparation condition of the composition, the curing temperature, the heat resistance of adherends, and the stability during the storage time. Especially preferable is an organic peroxide having a decomposition temperature giving a half-life period of 10 hours of 70° C. or higher.

Examples of the organic peroxide include t-butyl peroxy-2-ethylhexylmonocarbonate, t-butyl peroxyisopropylmonocarbonate, t-hexyl peroxyisopropylmonocarbonate, 2,5-dimethyl-2,5-bis(t-butylperoxy)hexane, 2,5-dimethyl-2,5-bis(t-butylperoxy)-3-hexyne, 2,5-dimethyl-2,5-di(2-ethylhexanoylperoxy)hexane, 2,5-dimethylhexane-2,5-dihydroperoxide, di-t-butyl peroxide, dicumyl peroxide, α,α′-bis(t-butylperoxyisopropyl)benzene, n-butyl-4,4-bis(t-butylperoxy)butane, 2,2-bis(t-butylperoxy)butane, 1,1-bis(t-hexylperoxy)-3,3,5-trimethylcyclohexane, 1,1-bis(t-butylperoxy)-3,3,5-trimethylcyclohexane, 1,1-bis(t-butylperoxy)cyclohexane, 2,2-bis(4,4-di-t-butylperoxycyclohexyl)propane, 1,1-bis(t-butylperoxy)cyclododecane, 1-cyclohexyl-1-methylethyl peroxy-2-ethylhexanoate, t-hexyl peroxy-2-ethylhexanoate, t-butyl peroxy-2-ethylhexanoate, 4-methylbenzoyl peroxide, benzoyl peroxide and t-butylbenzoyl peroxide. As the organic peroxide, especially preferable are t-butyl peroxy-2-ethylhexylmonocarbonate and 2,5-dimethyl-2,5-di(tert-butylperoxy)hexane. Thereby, there can be obtained the solar cell sealing film being well crosslinked and having excellent adhesion and transparency.

The content of the organic peroxide to be used for the composition of the solar cell sealing film according to the present invention is, with respect to 100 parts by mass of the ethylene-α-olefin copolymer, preferably 0.1 to 5 parts by mass, more preferably 0.2 to 3 parts by mass, and especially preferably 0.3 to 1.5 parts by mass. When the content of the organic peroxide is too low, the crosslinking speed decreases in crosslinking curing in some cases; and when too high, there arises a risk of causing bleedout.

[Silane Coupling Agent]

The silane coupling agent acts as an improving agent of the adhesive force of the solar cell sealing film with other members such as glass substrates. The silane coupling agent includes 3-chloropropyltrimethoxysilane, vinyltriethoxysilane, vinyltris(2-methoxyethoxy)silane, 3-methacryloxypropyltrimethoxysilane, vinyltriacetoxysilane, 3-glycidoxypropyltrimethoxysilane, 3-glycidoxypropyltriethoxysilane, 2-(3,4-epoxycyclohexyl)ethyltrimethoxysilane, vinyltrichlorosilane, 3-mercaptopropyltrimethoxysilane, 3-aminopropyltriethoxysilane and N-2-(aminoethyl)-3-aminopropyltrimethoxysilane. These silane coupling agents may be used singly or in a combination of two or more. Among these, 3-methacryloxypropyltrimethoxysilane is especially preferable.

The content of the silane coupling agent to be used for the composition of the solar cell-sealing film according to the present invention is, with respect to 100 parts by mass of the ethylene-α-olefin copolymer, preferably 0.1 to 0.7 parts by mass, more preferably 0.1 to 0.65 parts by mass, and especially preferably 0.1 to 0.5 parts by mass. When the content of the silane coupling agent is too low, the adhesive force is insufficient in some cases; and when too high, there arises a risk of causing bleedout.

[Crosslinking Auxiliary Agent]

The composition of the solar cell-sealing film according to the present invention may contain a crosslinking auxiliary agent, if needed. The crosslinking auxiliary agent can improve the gel fraction of the ethylene-α-olefin copolymer and improve the adhesion and the durability of the sealing film.

The content of the crosslinking auxiliary agent is, with respect to 100 parts by mass of the ethylene-α-olefin copolymer, usually 10 parts by mass or lower, preferably 0.1 to 5 parts by mass, and more preferably 0.1 to 2.5 parts by mass. Thereby, the solar cell sealing film better in the adhesion can be obtained.

The crosslinking auxiliary agent (usually, a compound having a radically polymerizable group as a functional group) includes trifunctional crosslinking auxiliary agents such as triallyl cyanurate and triallyl isocyanurate, and besides, monofunctional or bifunctional crosslinking auxiliary agents of (meth)acrylate esters (example, NK Esters). Among these, triallyl cyanurate and triallyl isocyanurate are preferable, and triallyl isocyanurate is especially preferable.

[Others]

The composition of the solar cell sealing film according to the present invention may contain other polymers such as low-density polyethylene (LDPE) as long as the advantage of the present invention is not impaired. Further in order to improve or regulate various physical properties (mechanical strength, adhesion, optical properties such as transparency, heat resistance, light resistance, crosslinking speed and the like), there may be contained one or more of various types of additives, if needed, such as a plasticizer, an ultraviolet absorbent, a light stabilizer, an antiaging agent, an acryloxy group-containing compound, a methacryloxy group-containing compound and/or an epoxy group-containing compound.

[Solar Cell Sealing Film]

The production of the solar cell sealing film according to the present invention may be carried out according to a known method. The sealing film can be produced, for example, by a method of preparing a composition obtained by mixing the ethylene-α-olefin copolymer with the above-mentioned materials by a known method using a Supermixer (high-speed fluidizing mixer), a roll mill or the like, and molding the mixture by usual extrusion, calender molding (calendering) or the like to thereby obtain a sheet-form material.

In the present invention, as a method for producing the solar cell sealing film, preferable is calender-molding of the above composition. In this case, as described above, the MFR of the ethylene-α-olefin copolymer is preferably 1 to 10 g/10 minutes, and more preferably 2 to 5 g/10 minutes. Thereby, a sealing film with higher stability during the storage time can be obtained. The sealing film obtained by the method according to the present invention is good in the laminatability and handleability when a solar cell is produced.

Further a sheet-form material can also be obtained by dissolving the above composition in the solvent and applying and drying the solution on a proper support by a proper coating machine (coater) to thereby form a coated film. Here, the heating temperature in film formation is preferably a temperature at which the organic peroxide does not react or scarcely reacts. The temperature is, for example, 40 to 90° C., and especially preferably 40 to 80° C. The thickness of the solar cell sealing film is not especially limited, and can suitably be selected depending on the applications. The thickness is usually in the range of 50 μm to 2 mm.

Since the decrease in the transparency is suppressed due to blending of magnesium hydroxide or magnesium oxide, the solar cell sealing film according to the present invention can be a sealing film particularly high in the transparency. Therefore, the haze value (according to JIS K7105 (2000)) after crosslinking of the solar cell sealing film according to the present invention is preferably 5.0 or lower, and more preferably 3.0 or lower. Further the light transmittance at a wavelength of 400 to 1,100 nm of the sealing film after crosslinking is preferably 90.5% or higher. Thereby, there can be obtained a solar cell exhibiting a high light conversion rate.

Further the present invention is also to provide a method of suppressing a decrease in the adhesive force during the storage time of the solar cell sealing film containing an ethylene-α-olefin copolymer polymerized using a metallocene catalyst, an organic peroxide and a silane coupling agent. That is, there is provided

a method of suppressing a decrease in the adhesive force during the storage time of the solar cell sealing film formed of a composition containing an ethylene-α-olefin copolymer polymerized using a metallocene catalyst, an organic peroxide and a silane coupling agent,

wherein the composition further contains, with respect to 100 parts by mass of the ethylene-α-olefin copolymer, 0.01 to 0.1 parts by mass of magnesium hydroxide or magnesium oxide.

Thereby, even if the solar cell sealing film is stored for a long period before being used for the production of a solar cell module, the decrease in the adhesive force can be suppressed without impairing the transparency of the solar cell sealing film. The preferable embodiments of the solar cell sealing film according to the present invention described above are also applied to the method according to the present invention.

[Solar Cell Module]

The structure of the solar cell module according to the present invention is not especially limited as long as the solar cell module has a structure in which solar cell elements are sealed with the solar cell sealing film according to the present invention. Examples thereof include a structure in which a solar cell is sealed by adhesively unifying the cell with the solar cell sealing film according to the present invention interposed between a front side transparent protection member and a backside protection member. Here, in the present invention, the side to be irradiated with light (light-receiving front side) of the solar cell is referred to as the “front side”; and the opposite side to the light-receiving surface of the solar cell is referred to as the “backside”. Since using the solar cell sealing film according to the present invention suppressed in the decrease in the adhesive force during the storage time without impairing the transparency, the solar cell module according to the present invention is a solar cell module high in the versatility in the production planning, reduced in the generation of faulty products, advantageous in the cost and high in the quality.

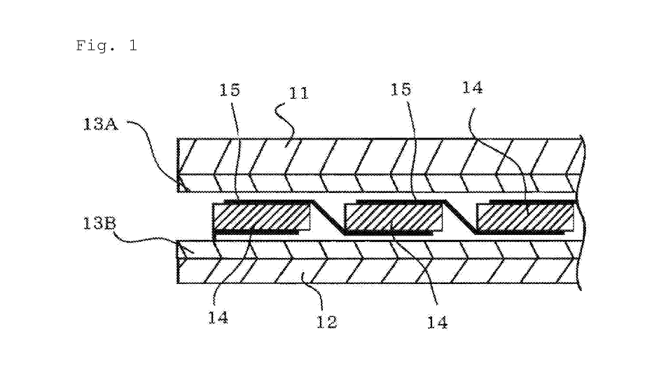

In order to sufficiently seal the solar cell, it suffices, for example, as shown in FIG. 1, if a front side transparent protection member 11, a front side sealing film 13A, a plurality of solar cells 14 (which are connected with interconnectors 15 formed of a conductive material such as a copper foil), a backside sealing film 13B and a backside protection member 12 are laminated in this order, and the sealing films are crosslinked to cure by a usual method including heating and pressurization. The heating and pressurization may be carried out, for example, by heating and pressure bonding the laminate by a vacuum laminator at a temperature of 135 to 180° C., further 140 to 180° C., particularly 155 to 180° C., for a degassing time of 0.1 to 5 min, at a pressing pressure of 0.1 to 1.5 kg/cm², and for a pressing time of 5 to 15 min. In the heating and pressurization, the ethylene-α-olefin copolymer contained in the front side sealing film 13A and the backside sealing film 13B can be crosslinked; and thus, the front side transparent protection member 11, the backside protection member 12 and the solar cells 14 can be unified through the front side sealing film 13A and the backside sealing film 13B, to thereby more sufficiently seal the solar cells 14.

The solar cell sealing film according to the present invention is used not only for solar cell modules using single crystalline or polycrystalline silicon crystal-based solar cells like one as shown in FIG. 1, but also for thin-film solar cell modules such as thin-film silicon-based, thin-film amorphous silicon-based and copper indium selenide (CIS)-based solar cell modules as long as they use a solar cell sealing film. In this case, examples of structures thereof include: a structure in which on a thin-film solar cell element layer formed on the surface of a front side transparent protection member such as a glass substrate, a polyimide substrate or a fluororesin-based transparent substrate by a chemical vapor deposition or the like, a backside sealing film and a backside protection member are laminated, and the laminate is adhesively unified; a structure in which on a solar cell element formed on the surface of a backside protection member, a front side sealing film and a front side transparent protection member are laminated, and the laminate is adhesively unified; and a structure in which a front side transparent protection member, a front side sealing film, a thin-film solar cell element, a backside sealing film and a backside protection member are laminated in this order, and the laminate is adhesively unified. Here, in the present invention, solar cells and thin-film solar cell elements are generically called solar cell elements.

The front side transparent protection member 11 is usually preferably a glass substrate such as a silicate glass. The thickness of the glass substrate is usually 0.1 to 10 mm, and preferably 0.3 to 5 mm. The glass substrate may be usually one chemically or thermally tempered.

As the backside protection member 12, preferably used are plastic films such as polyethylene terephthalate (PET) and polyamide. Further in consideration of the heat resistance and the wet heat resistance, there may be used fluorinated polyethylene films, particularly films obtained by laminating a fluorinated polyethylene film/Al/a fluorinated polyethylene film in this order.

Further, the solar cell sealing film according to the present invention is characterized by being a sealing film to be used for the front side and/or the backside of solar cell modules (including thin-film solar cell modules). Therefore, members other than the sealing film, such as the front side transparent protection member, the backside protection member and the solar cell, may have the same constitutions as in conventional known solar cell modules, and are not especially limited.

### Examples

Hereinafter, the present invention will be described by way of Examples.

1. Preparation of Solar Cell Sealing Films

Materials in a formulation indicated in Table 1 were supplied to a roll mill, and kneaded at 85° C. to thereby prepare a composition for a solar cell sealing film. The composition was calender molded at 85° C. and left to cool to thereby prepare a solar cell sealing film (thickness: 0.5 mm).

2. Evaluation Methods

(1) Stability During the Storage Time of the Adhesive Force of the Sealing Film

The each solar cell sealing film sample (1,000 mm in length×150 mm in width) was evaluated for the adhesive forces before the storage time and after the storage time (after 14 days). The storage was carried out by leaving the sample in a thermostatic chamber at a temperature of 40° C. at a humidity of 90 RH % for 14 days in the sample state of being bare without packaging. The adhesive force measurement was carried out as follows: a glass substrate (thickness: 3 mm), the sealing film, and a release PET film (thickness: 0.75 μm) were laminated in this order and temporarily pressure bonded at 90° C. for 10 minutes, and then heated in an oven at 155° C. for 45 minutes to crosslink the ethylene-α-olefin copolymer to obtain a sample; then, the sealing film was partially peeled from the glass substrate and folded by 180°; and the peeling force at a tensile rate of 100 mm/min was measured using a tensile tester (Autograph, manufactured by Shimadzu Corp.). The peeling force was taken as a glass adhesive force [N/cm] (180° folding peel test).

(2) Light Transmittance

On a sample obtained in the same manner as in the above (1) except that the storage period of the solar cell sealing film was 0 day, the spectral measurement of the light transmittance at a wavelength of 400 to 1,100 nm was carried out using a spectrophotometer (U-4100 (manufactured by Hitachi, Ltd.)), and the average value was taken as a light transmittance (%).

(3) Haze Value

For the same sample as in (2), the haze value (%) was measured according to JIS K7105 (2000) by using a haze meter (NDH2000, manufactured by Nippon Denshoku Industries Co., Ltd.).

3. Evaluation Results

The evaluation results are shown in the following Tables.

TABLE 1

| | | | | Comparative | Comparative | Example | Example | Example | Example | Example |
|---|---|---|---|---|---|---|---|---|---|---|
| | | | | Example 1 | Example 2 | 1 | 2 | 3 | 4 | 5 |
| Formulation | ethylene-α-olefin copolymer*1 | | | 100 | 100 | 100 | 100 | 100 | 100 | 100 |
| (parts by | organic peroxide*2 | | | 1 | 1 | 1 | 1 | 1 | 1 | 1 |
| mass) | silane coupling agent*3 | | | 0.3 | 0.3 | 0.3 | 0.3 | 0.3 | 0.3 | 0.3 |
| | ultraviolet absorbent*4 | | | 0.2 | 0.2 | 0.2 | 0.2 | 0.2 | 0.2 | 0.2 |
| | additive (1)*5 | | | 0 | 0.001 | 0.01 | 0.02 | 0.025 | 0.03 | 0.05 |
| | additive (2)*6 | | | — | — | — | — | — | — | — |
| BET Specific Surface Area of additive (m²/g) | | | | — | 60 | 60 | 60 | 60 | 60 | 60 |
| Average Particle Diameter of additive (μm) | | | | — | 7 | 7 | 7 | 7 | 7 | 7 |
| Evaluation | Adhesive | Storage | 0 | 23.5 | 22.8 | 22 | 21.5 | 20.5 | 20.8 | 19.9 |
| Results | Force | Period | 14 | 5.8 | 6 | 8 | 8.2 | 8.5 | 9.1 | 11.1 |
| | (N/cm) | (days) | | | | | | | | |

| | | | | | | | |
|---|---|---|---|---|---|---|---|
| Haze Value | 1 | 1 | 1.1 | 1.3 | 1.4 | 1.5 | 2.1 |
| Light Transmittance (%) | 90.9 | 90.9 | 90.9 | 90.9 | 90.8 | 90.9 | 90.8 |

| | | | | Example | Example | Example | Comparative | Comparative | Comparative |
|---|---|---|---|---|---|---|---|---|---|
| | | | | 6 | 7 | 8 | Example 3 | Example 4 | Example 5 |
| Formulation | ethylene-α-olefin copolymer*1 | | | 100 | 100 | 100 | 100 | 100 | 100 |
| (parts by | organic peroxide*2 | | | 1 | 1 | 1 | 1 | 1 | 1 |
| mass) | silane coupling agent*3 | | | 0.3 | 0.3 | 0.3 | 0.3 | 0.3 | 0.3 |
| | ultraviolet absorbent*4 | | | 0.2 | 0.2 | 0.2 | 0.2 | 0.2 | 0.2 |
| | additive (1)*5 | | | 0.075 | 0.09 | 0.1 | 0.3 | 0.5 | — |
| | additive (2)*6 | | | — | — | — | — | — | 0.1 |
| BET Specific Surface Area of additive (m²/g) | | | | 60 | 60 | 60 | 60 | 60 | 5 |
| Average Particle Diameter of additive (μm) | | | | 7 | 7 | 7 | 7 | 7 | 1 |
| Evaluation | Adhesive | Storage | 0 | 19.5 | 19 | 21.7 | 20.2 | 24.6 | 19.1 |
| Results | Force | Period | 14 | 12.4 | 13.5 | 16.7 | 20.3 | 23.7 | 0.9 |
| | (N/cm) | (days) | | | | | | | |

| | | | | | | |
|---|---|---|---|---|---|---|
| Haze Value | 2.7 | 3.2 | 3.5 | 9.6 | 13.7 | 1.4 |
| Light Transmittance (%) | 90.8 | 90.8 | 90.8 | 90.3 | 89.8 | 90.8 |

Remarks)
*1KS340T (manufactured by Japan Polyethylene Corp., a metallocene plastomer (density: 0.880 g/cm³, MFR (190° C.): 3.5 g/10 min))
*2Perbutyl E (manufactured by NOF Corp., t-butyl peroxy-2-ethylhexylmonocarbonate)
*3KBM503 (manufactured by Shin-Etsu Silicone Co., Ltd., 3-methacryloxypropyltrimethoxysilane)
*4CHIMASSORB 81 (manufactured by BASF, 2-hydroxy-4-n-octoxybenzophenone)
*5magnesium hydroxide (average particle diameter: 7 μm, BET specific surface area: 60 m²/g)
*6aluminum hydroxide (average particle diameter: 1 μm, BET specific surface area: 5 m²/g)

TABLE 2

| | | | | Comparative | Example | Example | Example | Example | Example | Example |
|---|---|---|---|---|---|---|---|---|---|---|
| | | | | Example 6 | 9 | 10 | 11 | 12 | 13 | 14 |
| Formulation | ethylene-α-olefin copolymer*1 | | | 100 | 100 | 100 | 100 | 100 | 100 | 100 |
| (parts by | organic peroxide*2 | | | 1 | 1 | 1 | 1 | 1 | 1 | 1 |
| mass) | silane coupling agent*3 | | | 0.3 | 0.3 | 0.3 | 0.3 | 0.3 | 0.3 | 0.3 |
| | ultraviolet absorbent*4 | | | 0.2 | 0.2 | 0.2 | 0.2 | 0.2 | 0.2 | 0.2 |
| | additive A*7 | | | 0.09 | 0.09 | 0.09 | 0.09 | 0.09 | 0.09 | 0.09 |
| BET Specific Surface Area of additive A (m²/g) | | | | 10 | 30 | 50 | 150 | 200 | 250 | 60 |
| Average Particle Diameter of additive A (μm) | | | | 7 | 7 | 7 | 7 | 7 | 7 | 0.05 |
| Evaluation | Adhesive | Storage | 0 | 21.5 | 21.8 | 22.7 | 23.2 | 20.4 | 23.4 | 22.8 |
| Results | Force | Period | 14 | 8.9 | 12.5 | 16.1 | 20.5 | 18.4 | 16.5 | 15.8 |
| | (N/cm) | (days) | | | | | | | | |

| | | | | | | | |
|---|---|---|---|---|---|---|---|
| Haze Value | 3.1 | 3.2 | 3.2 | 3.3 | 6.8 | 8.4 | 3.8 |
| Light Transmittance (%) | 90.8 | 90.8 | 90.8 | 90.8 | 90.4 | 90.4 | 90.7 |

| | | | | Example | Example | Example | Example | Example | Example | Example |
|---|---|---|---|---|---|---|---|---|---|---|
| | | | | 15 | 16 | 17 | 18 | 19 | 20 | 21 |
| Formulation | ethylene-α-olefin copolymer*1 | | | 100 | 100 | 100 | 100 | 100 | 100 | 100 |
| (parts by | organic peroxide*2 | | | 1 | 1 | 1 | 1 | 1 | 1 | 1 |
| mass) | silane coupling agent*3 | | | 0.3 | 0.3 | 0.3 | 0.3 | 0.3 | 0.3 | 0.3 |
| | ultraviolet absorbent*4 | | | 0.2 | 0.2 | 0.2 | 0.2 | 0.2 | 0.2 | 0.2 |
| | additive A*7 | | | 0.09 | 0.09 | 0.09 | 0.09 | 0.09 | 0.09 | 0.09 |
| BET Specific Surface Area of additive A (m²/g) | | | | 60 | 60 | 60 | 60 | 60 | 60 | 60 |
| Average Particle Diameter of additive A (μm) | | | | 0.1 | 3 | 5 | 7 | 8 | 10 | 12 |
| Evaluation | Adhesive | Storage | 0 | 21.7 | 21.5 | 20.3 | 19 | 20.5 | 20.1 | 19.1 |
| Results | Force | Period | 14 | 16.7 | 14.4 | 15.7 | 13.5 | 13.2 | 14.9 | 13.4 |
| | (N/cm) | (days) | | | | | | | | |

| | | | | | | | |
|---|---|---|---|---|---|---|---|
| Haze Value | 3.6 | 3.4 | 3.2 | 3.2 | 3.2 | 3.3 | 3.4 |
| Light Transmittance (%) | 90.8 | 90.8 | 90.8 | 90.8 | 90.8 | 90.8 | 90.8 |

Remarks)
*1 to *4the same as in Table 1
*7a magnesium hydroxide having the average particle diameter and the BET specific surface area as indicated in Table

TABLE 3

| | | | | Comparative | Example | Example | Example | Example | Example | Comparative |
|---|---|---|---|---|---|---|---|---|---|---|
| | | | | Example 7 | 22 | 23 | 24 | 25 | 26 | Example 8 |
| Formulation | ethylene-α-olefin copolymer*1 | | | 100 | 100 | 100 | 100 | 100 | 100 | 100 |
| (parts by | organic peroxide*2 | | | 1 | 1 | 1 | 1 | 1 | 1 | 1 |
| mass) | silane coupling agent*3 | | | 0.3 | 0.3 | 0.3 | 0.3 | 0.3 | 0.3 | 0.3 |
| | ultraviolet absorbent*4 | | | 0.2 | 0.2 | 0.2 | 0.2 | 0.2 | 0.2 | 0.2 |
| | additive (3)*8 | | | 0.001 | 0.01 | 0.03 | 0.05 | 0.09 | 0.1 | 0.3 |
| BET Specific Surface Area of additive (m²/g) | | | | 60 | 60 | 60 | 60 | 60 | 60 | 60 |
| Average Particle Diameter of additive (μm) | | | | 7 | 7 | 7 | 7 | 7 | 7 | 7 |
| Evaluation | Adhesive | Storage | 0 | 21.6 | 22.1 | 19.7 | 21.1 | 20.8 | 18.9 | 20.6 |
| Results | Force | Period | 14 | 4.1 | 6.9 | 8.9 | 12.4 | 14.1 | 14.9 | 18.6 |
| | (N/cm) | (days) | | | | | | | | |

| | | | | | | | |
|---|---|---|---|---|---|---|---|
| Haze Value | 1 | 1.2 | 1.5 | 2.2 | 3.1 | 3.4 | 10.2 |
| Light Transmittance (%) | 90.9 | 90.9 | 90.8 | 90.8 | 90.8 | 90.7 | 90.2 |

Remarks)
*1 to *4the same as in Table 1
*8a magnesium oxide (the average particle diameter: 7 μm, the BET specific surface area: 60 m²/g)

TABLE 4

| | | | | Com- | | | | | | | | | | |
|---|---|---|---|---|---|---|---|---|---|---|---|---|---|---|
| | | | | para- | | | | | | | | | | |
| | | | | tive | | | | | | | | | | |
| | | | | Exam- | Exam- | Exam- | Exam- | Exam- | Exam- | Exam- | Exam- | Exam- | Exam- | Exam- |
| | | | | ple 9 | ple 27 | ple 28 | ple 29 | ple 30 | ple 31 | ple 32 | ple 33 | ple 34 | ple 35 | ple 36 |
| Formulation | ethylene-α-olefin | | | 100 | 100 | 100 | 100 | 100 | 100 | 100 | 100 | 100 | 100 | 100 |
| (parts by | copolymer*1 | | | | | | | | | | | | | |
| mass) | organic peroxide*2 | | | 1 | 1 | 1 | 1 | 1 | 1 | 1 | 1 | 1 | 1 | 1 |
| | silane coupling agent*3 | | | 0.3 | 0.3 | 0.3 | 0.3 | 0.3 | 0.3 | 0.3 | 0.3 | 0.3 | 0.3 | 0.3 |
| | ultraviolet absorbent*4 | | | 0.2 | 0.2 | 0.2 | 0.2 | 0.2 | 0.2 | 0.2 | 0.2 | 0.2 | 0.2 | 0.2 |
| | additive B*9 | | | 0.09 | 0.09 | 0.09 | 0.09 | 0.09 | 0.09 | 0.09 | 0.09 | 0.09 | 0.09 | 0.09 |
| BET Specific Surface Area of additive B | | | | 10 | 30 | 50 | 150 | 200 | 250 | 60 | 60 | 60 | 60 | 60 |
| (m²/g) | | | | | | | | | | | | | | |
| Average Particle Diameter of additive B | | | | 7 | 7 | 7 | 7 | 7 | 7 | 0.05 | 0.1 | 5 | 10 | 12 |
| (μm) | | | | | | | | | | | | | | |
| Evaluation | Adhesive | Storage | 0 | 22.0 | 21.4 | 21.6 | 19.8 | 20.6 | 20.1 | 19.7 | 20.6 | 21.9 | 20.2 | 22.3 |
| Results | Force | Period | 14 | 6.9 | 13.1 | 15.9 | 18.4 | 17.8 | 15.8 | 13.7 | 14.5 | 15.0 | 13.3 | 14.2 |
| | (N/cm) | (days) | | | | | | | | | | | | |

| | | | | | | | | | | | |
|---|---|---|---|---|---|---|---|---|---|---|---|
| Haze Value | 3.1 | 3.2 | 3.2 | 3.3 | 6.5 | 7.8 | 4.0 | 3.9 | 3.3 | 3.5 | 3.6 |
| Light Transmittance (%) | 90.8 | 90.8 | 90.8 | 90.8 | 90.5 | 90.5 | 90.6 | 90.8 | 90.8 | 90.8 | 90.7 |

Remarks)
*1 to *4the same as in Table 1
*9a magnesium oxide having the average particle diameter and the BET specific surface area as indicated in Table

As indicated in the above Tables, the sealing films in which magnesium hydroxide or magnesium oxide was blended in an amount of the range of the present invention were suppressed in the decrease in the adhesive force even when the storage period became long, and had high transparency from the results of the haze value and the light transmittance. By contrast, the sealing films of Comparative Examples 1, 2 and 7, in which no magnesium hydroxide was blended or only an extremely trace amount thereof was blended, were decreased in the adhesive force when the storage period became long. On the other hand, the sealing films of Comparative Examples 3, 4 and 8, in which the amount of magnesium hydroxide blended was large, exhibited a remarkably raised haze value and thus impaired transparency. Further, the sealing film of Comparative Example 5, in which aluminum hydroxide, a similar basic hydroxide to magnesium hydroxide, was blended, could not be suppressed in the decrease in the adhesive force during the storage time.

### INDUSTRIAL APPLICABILITY

According to the present invention, since the solar cell sealing film is suppressed in the decrease in the adhesive force during the storage time without impairing the transparency, there can be provided a solar cell module reduced in the generation of faulty products and high in the quality.

### REFERENCE SIGNS LIST

11 FRONT SIDE TRANSPARENT PROTECTION MEMBER
12 BACKSIDE PROTECTION MEMBER
13A FRONT SIDE SEALING FILM
13B BACKSIDE SEALING FILM
14 SOLAR CELL
15 INTERCONNECTOR

1. A solar cell sealing film formed of a composition comprising an ethylene-α-olefin copolymer polymerized using a metallocene catalyst, an organic peroxide and a silane coupling agent, wherein the composition further comprises 0.01 to 0.1 parts by mass of magnesium hydroxide or magnesium oxide with respect to 100 parts by mass of the ethylene-α-olefin copolymer, and the magnesium hydroxide or the magnesium oxide has a BET specific surface area of 30 m²/g or larger.

2. The solar cell sealing film according to claim 1, wherein the magnesium hydroxide or the magnesium oxide has a BET specific surface area of 30 to 200 m²/g.

3. The solar cell sealing film according to claim 1, wherein the magnesium hydroxide or the magnesium oxide has a BET specific surface area of 50 to 160 m²/g.

4. The solar cell sealing film according to claim 1, wherein the magnesium hydroxide or the magnesium oxide has an average particle diameter of 0.1 to 10 μm.

5. The solar cell sealing film according to claim 1, wherein the ethylene-α-olefin copolymer has a melt flow rate (MFR) of 1 to 10 g/10 minutes as measured according to JIS K7210 under the condition of 190° C. and a load of 21.18 N.

6. The solar cell sealing film according to claim 1, wherein the solar cell sealing film after being crosslinked has a haze value of 5.0 or lower as measured according to JIS K7105, and a light transmittance at a wavelength of 400 to 1,100 nm of 90.5% or higher.

7. A method for producing a solar cell sealing film, comprising calender-molding a composition comprising an ethylene-α-olefin copolymer polymerized using a metallocene catalyst, an organic peroxide and a silane coupling agent, and further comprising 0.01 to 0.1 parts by mass of magnesium hydroxide or magnesium oxide having a BET specific surface area of 30 m²/g or larger with respect to 100 parts by mass of the ethylene-α-olefin copolymer.

8. The method for producing a solar cell-sealing film according to claim 7, wherein the ethylene-α-olefin copolymer has a melt flow rate (MFR) of 1 to 10 g/10 minutes as measured according to JIS K7210 under the condition of 190° C. and a load of 21.18 N.

9. A solar cell module obtained by sealing a solar cell element with a solar cell sealing film according to claim 1.

10. A method for suppressing a decrease in an adhesive force during a storage time of a solar cell sealing film formed of a composition comprising an ethylene-α-olefin copolymer polymerized using a metallocene catalyst, an organic peroxide and a silane coupling agent, wherein the composition further comprises 0.01 to 0.1 parts by mass of magnesium hydroxide or magnesium oxide having a BET specific surface area of 30 m²/g or larger with respect to 100 parts by mass of the ethylene-α-olefin copolymer.
